(19) United States
(12) Patent Application Publication
(10) Pub. No.: US 2022/0216355 A1
(43) Pub. Date: Jul. 7, 2022

(54) THREE-DIMENSIONAL SOLAR CELL AND METHOD

(71) Applicant: KING ABDULLAH UNIVERSITY OF SCIENCE AND TECHNOLOGY, Thuwal (SA)

(72) Inventors: Muhammad Mustafa HUSSAIN, Hercules, CA (US); Nazek Mohamad EL-ATAB, Thuwal (SA); Rabab Riyad BAHABRY, Thuwal (SA)

(21) Appl. No.: 17/609,030

(22) PCT Filed: May 12, 2020
(86) PCT No.: PCT/IB2020/054482

§ 371 Date: Nov. 5, 2021

Related U.S. Application Data
(60) Provisional application No. 62/851,227, filed on May 22, 2019.

(51) Int. Cl. H01L 31/0352; H01L 31/0224; H01L 31/0392; H01L 31/048

(52) U.S. Cl. CPC H01L 31/035281; H01L 31/0481; H01L 31/03926; H01L 31/022433

(57) ABSTRACT

A three-dimensional (3D) solar cell includes an active, rigid, and flat material configured to transform solar energy into electrical energy, wherein the active, rigid, and flat material is shaped as first and second petals, each petal having plural sides, plural electrodes formed on a backside of the active, rigid, and flat material, a flexible transparent substrate coating the backside of the active, rigid, and flat material and the plural electrodes, plural trenches formed in the active, rigid, and flat material, to partially expose the plural electrodes and the substrate, and a transparent polymer configured to attach a side from the first petal to a side from the second petal.

### CROSS-REFERENCE TO RELATED APPLICATIONS

This application claims priority to U.S. Provisional Patent Application No. 62/851,227, filed on May 22, 2019, entitled “OMNI VIEW SOLAR CELLS WITH SELF-CLEANING AND SELF-COOLING ABILITY,” the disclosure of which is incorporated herein by reference in its entirety.

### BACKGROUND

### Technical Field

Embodiments of the subject matter disclosed herein generally relate to a three-dimensional (3D) solar cell and associated system for light harvesting, and more particularly, to a solar cell that is shaped to be non-flat, which improves energy harvesting, and dust and thermal management.

### Discussion of the Background

In today's photovoltaic (PV) industry, silicon-based solar cells dominate almost 90% of the world's PV production due to their low-cost, good-efficiency, exceptional reliability, and due to the high natural abundance of the silicon material. Even though alternative materials such as III-V semiconductors, quantum dots/wires, and organics, have proven promising for solar cell applications, however, significant amount of research is continuously being conducted on unconventional techniques to exploit monocrystalline silicon solar cells in an attempt to maximize their light harvesting and increase their power output for the same ground area. These methodologies range from innovative light trapping schemes to advanced cell designs, creative doping profiles, and cutting-edge manufacturing techniques.

The ultimate goals in PV research are: 1) to increase the efficiency of the solar cells, 2) enable them to capture the maximum amount of sunlight, 3) reduce the heat generation, and 4) mitigate dust accumulation.

The harvesting of sunlight can be maximized by equipping the solar modules with a mechanical sun tracking system so that the light rays always fall perpendicularly on the surface of the cell as the orientation of the sun changes during the day and over the year. However, such systems add to the total cost and weight of the solar module and make it unsuitable for many applications including the rooftop of houses and offices. In addition, solar cells should be designed not only to capture light from the direct exposure to light (direct beam), but they should also be able to exploit energy given out in the form of a diffuse beam and recycle the beams reflected from the background and surroundings of the solar cell.

To achieve these purposes, multiple pioneering techniques have been developed including the bi-facial structure of silicon solar cells, which are capable of harvesting the sunlight reflected by the background, and therefore promise an increase in power output by up to about 35% with respect to the traditional solar cells. Another creative method is based on the fabrication of micro-spherical silicon solar cells to collect direct and diffuse beams with better efficiency [1, 2]. However, the microspheres are integrated on a flat substrate and therefore cannot make use of the background reflected beams.

Other techniques focus on solving the heat generation/dissipation and dust accumulation challenges using unique solar cell stacks and encapsulation materials. Nevertheless, all of the aforementioned efforts focus on and tackle only one aspect of the multiple PV research challenges.

Thus, there is a need for a new solar cell and solar cell system that are capable of improving on more of the PV goals noted above.

### BRIEF SUMMARY OF THE INVENTION

According to an embodiment, there is a three-dimensional (3D) solar cell that includes an active, rigid, and flat material configured to transform solar energy into electrical energy, wherein the active, rigid, and flat material is shaped as first and second petals, each petal having plural sides, plural electrodes formed on a backside of the active, rigid, and flat material, a flexible transparent substrate coating the backside of the active, rigid, and flat material and the plural electrodes, plural trenches formed in the active, rigid, and flat material, to partially expose the plural electrodes and the substrate, and a transparent polymer configured to glue a side from the first petal to a side from the second petal.

According to another embodiment, there is a three-dimensional (3D) solar cell that includes a spherical base, plural electrodes wrapped around the spherical base, and an active material on which the plural electrodes are formed on, and the active material is configured to transform solar energy into electrical energy, wherein the active material is shaped to have plural regions, each region having plural sides. The active material extends over the spherical base and has a spherical shape.

According to still another embodiment, there is a power generation system that includes a rigid frame and plural solar cells mechanically connected to each other to form a net. Each of the plural solar cells is shaped as a sphere, the plural solar cells are configured to generate electrical energy from solar energy, and each solar cell is electrically and mechanically connected to other solar cells of the plural solar cells.

According to yet another embodiment, there is a method for making a three-dimensional, 3D, solar cell, and the method includes providing a spherical base, providing a flat and rigid solar cell, making plural trenches in an active material of the flat and rigid solar cell, to partially expose plural electrodes and a flexible transparent substrate of the flat and rigid solar cell, removing parts of the active material to form first and second regions, each region having plural sides, wrapping the first and second regions around the spherical base to form the 3D solar cell, and coating the wrapped first and second regions with a transparent polymer to connect a side of the first region to a side of the second region.

### BRIEF DESCRIPTION OF THE DRAWINGS

Fora more complete understanding of the present invention, reference is now made to the following descriptions taken in conjunction with the accompanying drawings, in which:

FIG. 1 is a schematic diagram of a 3D solar cell;

FIGS. 2A to 2F illustrate a method for making a solid and flat solar cell to be flexible;

FIG. 3 illustrates interdigitated electrodes used for forming a solar cell;

FIGS. 4A to 4D illustrate a method for making a spherical solar cell;

FIGS. 5A to 5C show various views of the spherical solar cell at microscopic level;

FIG. 6 illustrates the transmittance of the PDMS (polymer) used as a hard mask on the solar cell before and after the flexing process in the deep reactive ion etching tool;

FIGS. 7A and 7B illustrate the current density and power density of the spherical solar cell relative to the flat solar cell with the same projection area;

FIG. 8 illustrates the power output of the spherical solar cell with a black background and with a white background;

FIG. 9 illustrates a set-up for testing the power generation of the spherical solar cell with various backgrounds;

FIGS. 10A to 10C illustrate various parameters measured for the spherical solar cell with different backgrounds;

FIGS. 11A to 12 illustrate the effect on power generation of changing a height of the spherical solar cell relative to a background material;

FIGS. 13A and 13B illustrate the effect of the surface of the background material on the efficiency of the spherical solar cell;

FIGS. 14A and 14B illustrate the temperature and power output of the spherical and flat solar cells;

FIGS. 15A and 15B illustrate the dust influence on the spherical and flat solar cells;

FIG. 16 illustrates a network array of spherical solar cells for generating electrical energy; and

FIG. 17 is a flowchart of a method for making a spherical solar cell.

### DETAILED DESCRIPTION OF THE INVENTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to a spherical solar cell. However, the embodiments to be discussed next are not limited to a spherical shaped solar cell, but may be applied to other 3D shapes, e.g., cube, pyramid, dodecahedron, rhombic triacontahedron, which are generically called herein polyhedron.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

According to an embodiment, an innovative 3D solar cell design discussed herein with regard to the figures is capable of harvesting light three-dimensionally, by tracking directly the sunlight, exploiting diffuse beams, and recycling background reflected light. This 3D solar cell architecture is based on monocrystalline silicon solar cells with high efficiency (19%) and is fabricated using a corrugation technique that transforms rigid solar cells into flexible ones with a maintained electrical performance [3]. The corrugation technique and 3D design of the solar cells enhance the heat dissipation and reduce dust accumulation, as discussed later.

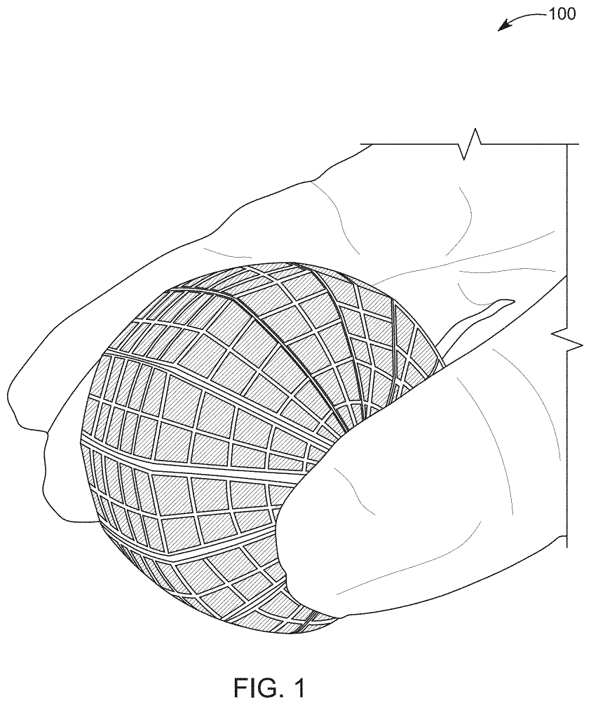

FIG. 1 shows a 3D (also called non-flat) solar cell 100 having a diameter of about 5 cm. It is noted that the 3D solar cell 100 may be manufactured to have any desired size. Although FIG. 1 shows the 3D solar cell 100 having a spherical-like shape, other shapes may be used. An object having a spherical-like shape is defined herein as a 3D object that can fit inside a sphere (i.e., it is circumscribed by the interior surface of the sphere) and touches the interior of the sphere at plural points, e.g., more than 5. Thus, a spherical-like shape is not exactly a spherical shape, but is close to being one. The spherical-like shape, as illustrated in FIG. 1, is made with many small planar shapes that are adjacent to each other.

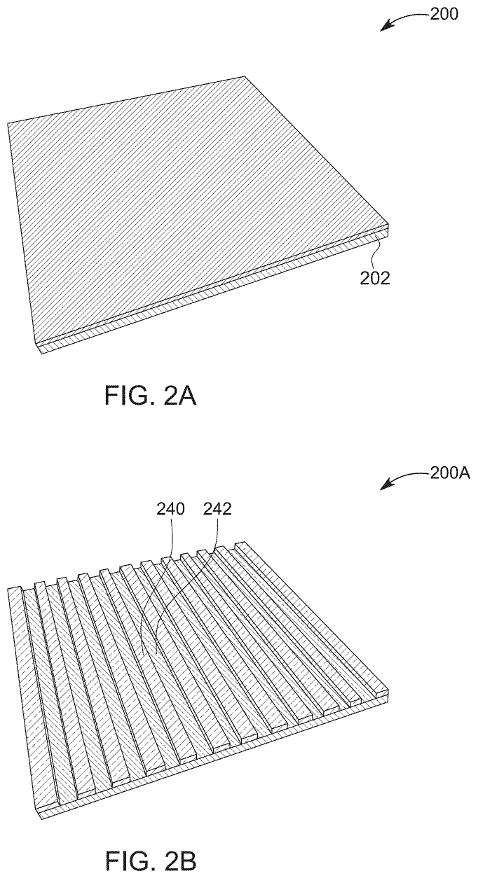

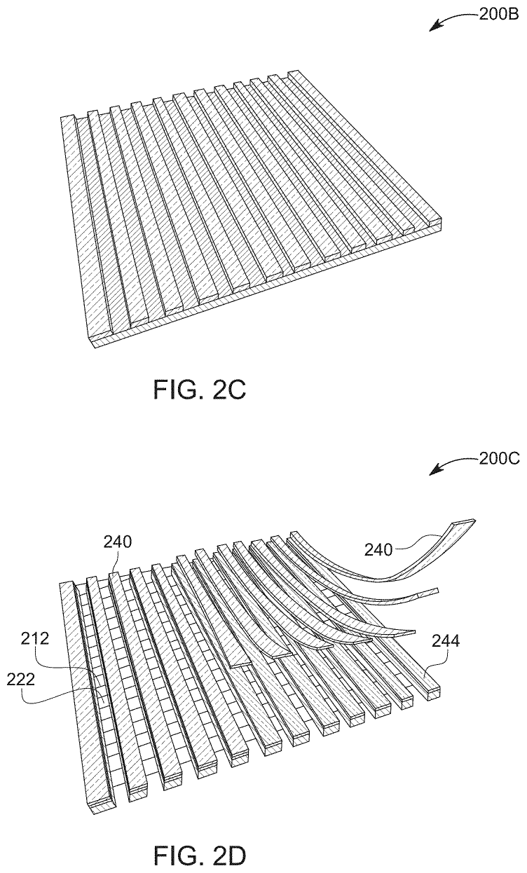

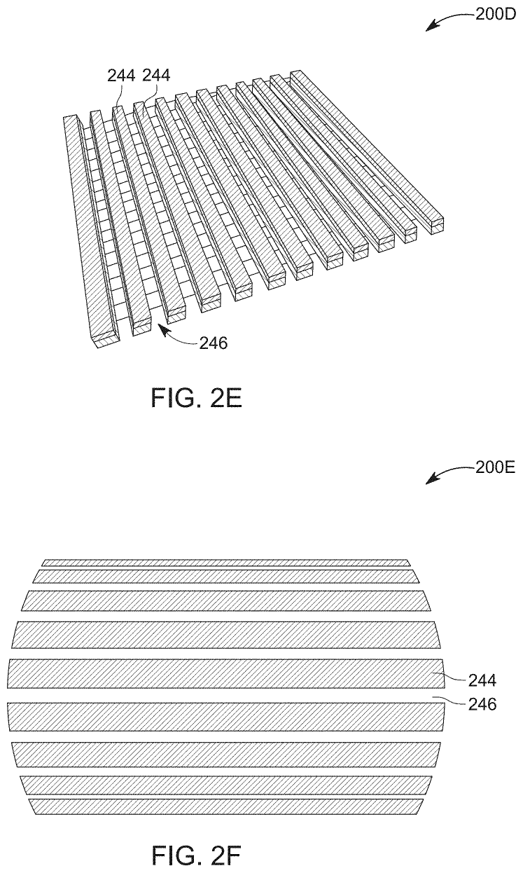

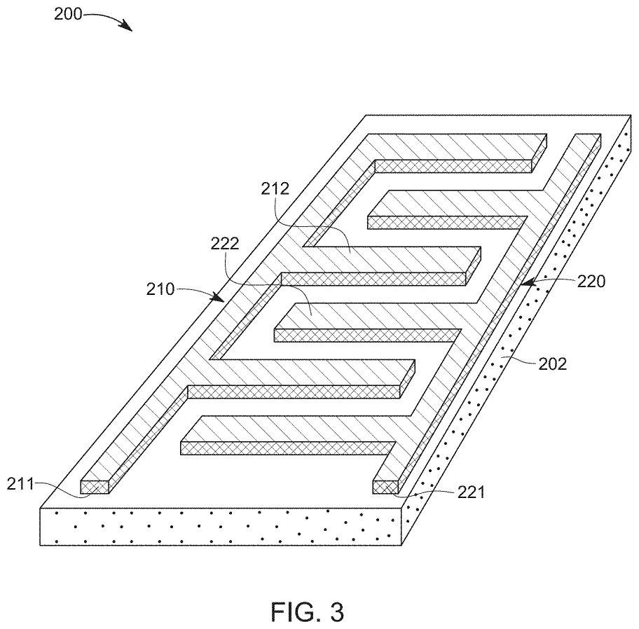

A method for making the 3D solar cell shown in FIG. 1 is now discussed with regard to FIGS. 2A to 2F. FIG. 2A shows an interdigitated back contact (IBC) rigid and flat solar cell 200 built on a wafer 202 having a size of 127 cm by 127 cm. Each wafer 202, which is shown in more detail in FIG. 3, includes an interdigitated p electrode 210 having plural fingers 212 and an n electrode 220 having plural fingers 222. The fingers 212 and 222 extend parallel to each other, but in opposite directions, as also shown in FIG. 3. The wafer 202 is made of bulk silicon with a thickness of about 170 μm. FIG. 3 further shows that the electrodes terminate with a corresponding pad 211, 221, that is configured to connect to a load (not shown) to deliver the electrical power generated by the solar cell.

Returning to FIG. 2A, it is noted that the solar cell 200 is flat and rigid and cannot be bent. To transform this flat and rigid solar cell to make it more appropriate for making a 3D solar cell, the solar cell 200 is covered in step 200A with photo-resists material coating followed by a hard mask 240 (for example, Kapton tape), to obtain the strips 242 of exposed material. The backside of the solar cell is coated with PDMS to be used as a substrate. In step 200B, the mask 240 is exposed to UV radiation to cure the photo-resists material. It should be noted that in another method, PDMS could be used as a hard mask instead of Kapton and which can be directly patterned using a CO₂ laser. In step 200C, deep reactive ion etching (DRIE) processing (other processing may also be applied) is applied to remove the active solar cell material, but not the electrodes 210 and 220 or the substrate 202 (see FIG. 3), corresponding to the strips 242, to partially expose the finger electrodes 212 and 222, as illustrated in FIG. 2D. In step 200D, the masks 240 are removed (the photoresist tape helps in this regard to easily remove the Kapton material without leaving any residue on the active solar area of the solar cell) exposing the portions 244 (active material) of the solar cell that remain intact. Because of the trenches 246 formed between the strips 244 of the active material, the final solar cell 200 shown in FIG. 2E is now bendable. Thus, in step 200E, the solar cell 200 is bended as illustrated in FIG. 2F. This technique is called herein the corrugation technique. In one optional step, it is also possible to remove by DRIE processing a part of the substrate 202, to make it thinner, and thus flexible. The part that is removed from the substrate 202 is opposite to the face of the substrate on which the electrodes are formed.

The spherical solar cell 100 is fabricated using the above discussed corrugation technique applied on commercially available monocrystalline silicon solar cells 200 (e.g., 5 inch by 5 inch) with interdigitated back contacts (IBC) and high efficiency (19%). The corrugation technique has the capability to create between 100 and 200 μm, e.g., 138 μm-wide trenches 246 within the solar cell 200 resulting in a flexible structure with 5.6% loss of total area.

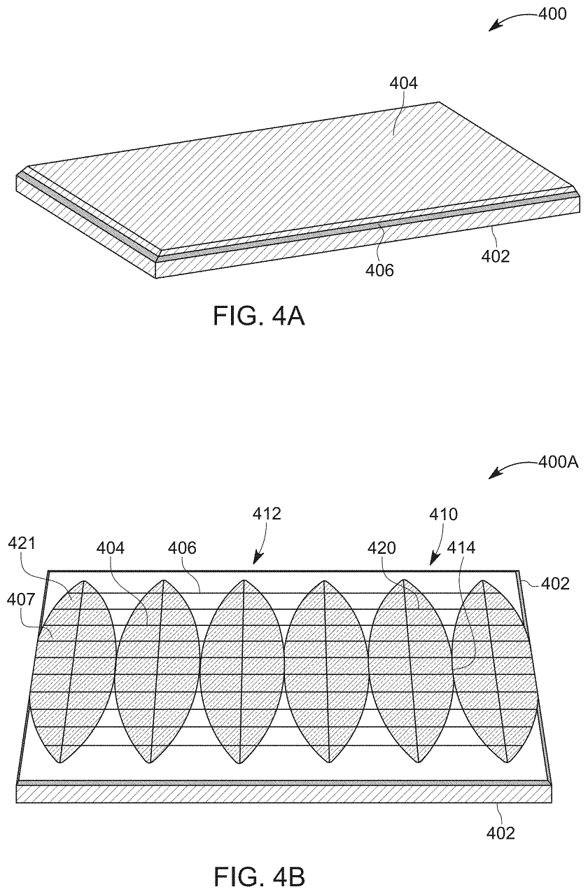

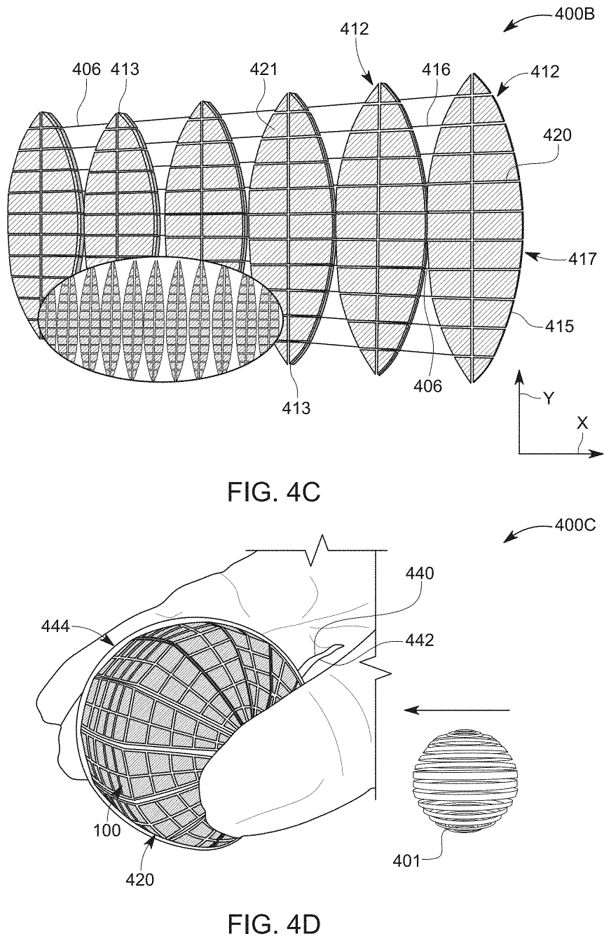

As illustrated in FIGS. 4A to 4D, the fabrication of the 3D solar cell 100 starts in FIG. 4A, with a commercially available wafer 400, similar to the wafer 200 shown in FIG. 2A. The wafer 400, which already has the semiconductor material or active material (e.g., c-Si material of thickness 170 microns) 404 and the IBC electrodes 406, is coated with a polydimethylsiloxane (PDMS) layer on its backside to act as a substrate 402. Then, the front side is covered with another PDMS layer 421, which is then patterned with a laser in step 400A, to obtain the patterned solar cell 410. In one application, a 200 μm of PDMS material is spin coated on the 5 inch by 5 inch solar cell 400 and cured at 60° C. for 2 hours to act as the mask. The PDMS layer 421 is patterned using a CO₂ laser with a power of 24 W, speed of 40 mm/s and a height of 1 mm. The exposed area of the active layer 404 is then etched using sulfur hexafluoride (SF6) and carbon fluoride (C4F8) in a deep reactive ion etching system (DRIE) at −20° C. The obtained solar cell is flexible with −135 μm wide trenches 407.

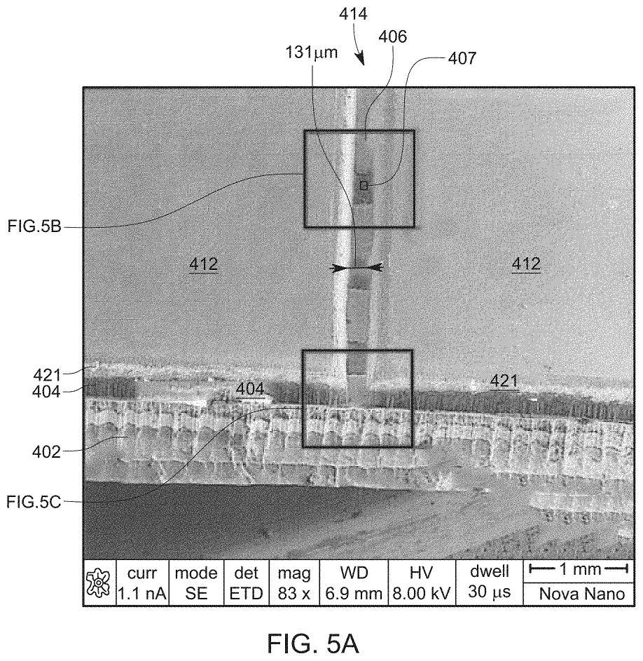

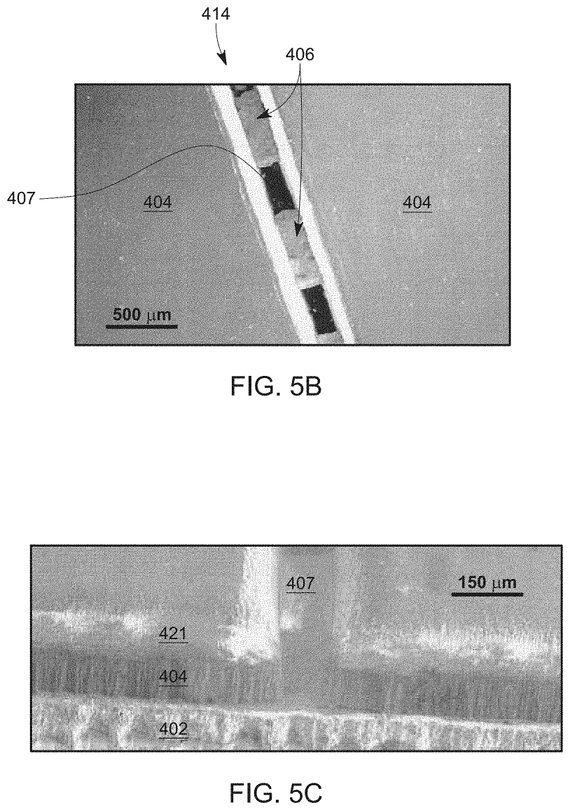

The patterned solar cell 410 has part of the active material 404 removed, but not the IBC electrodes 406 and the PDMS substrate 402, as shown in FIG. 4B. FIG. 4B shows that the remaining active material 404 has been shaped as petals 412 (or regions) while the connecting IBC electrodes 406 are intact even between the petals. The same is true for the transparent substrate 402. The petals 412 are still connected to each other at selected locations 414. The term “petal” is defined herein as being a 2D object that has a prolate spheroid shape. The selected locations 414 correspond to some of the trenches 407 formed in the active material 404, and they are chosen so that the petals/regions can be folded together to form the 3D solar cell 100 shown in FIG. 1. Note that in one embodiment, the selected locations 414 are processed so that the active material 404 is removed and only the IBC electrodes 406 are left, as shown in FIG. 5A. In this way, the petals 412 can be easily folded or bended at the selected locations 414 to form the desired 3D shape. In fact, the IBC electrodes 406 are bendable and therefore, to make any 3D architecture, they are bent or hidden accordingly, to allow all the edges of the petals to become adjacent and closer to each other, as illustrated in FIG. 4D. FIG. 5B shows in more detail the IBC electrodes 406 at the selected locations 414 while FIG. 5C shows in more detail the active material 404 formed over the substrate 402. Note that the regions 412 were shaped as petals in this embodiment because the goal of this embodiment was to obtain a spherical solar cell. However, if the goal is to obtain a polyhedron, then the regions 412 may be shaped differently than a petal.

Then, in step 400B, the DRIE processing (or equivalent processing) is applied to the patterned solar cell 410 to remove the active material 404 between the petals 412 and, within the petals, grooves 420 may be formed to make the petal flexible, so that the IBC electrodes 406 are left on the PDMS layer 402 in the spaces 416 from which the active material 404 has been removed. The spaces 416, as shown in FIG. 4C, are formed between the distal ends of the petals and within the grooves. The petals 412 remain attached to each other through IBC electrodes 406, as illustrated in FIG. 4C. For example, as shown in FIGS. 4B and 4C, the grooves 420 may extend along two axes X and Y, that are perpendicular to each other. The orientation of the grooves 420 is dictated by the final 3D shape of the solar cell 100. For example, if the shape of the 3D solar cell 100 is desired to be spherical-like, then plural grooves 420 extend transversely across each petal 412, and one groove 420 extends longitudinally along each petal 412. In this way, when the petals are folded and tucked together as shown in FIG. 4D, the 3D solar cell 100 resembles a sphere. In this step, the PDMS substrate 402 with the IBC electrodes 406 in between the distant petals are bent and folded such that the edge of the petals 412 become adjacent and closer to each other to form the 3D spherical shape. FIG. 4D further shows the two electrical contacts/pads 440 and 442. One contact is a positive contact and the other is a negative contact, which are connected to the IBC grid of the petals in order to harvest the electrical energy by the solar cell 400.

The folding action taking place in step 400C, may use a spherical base 401 for supporting the plural petals 412 when placed together. The base 401 may be made from a foam or other non-conducting material, so that it does not interfere with the electrical current generation. However, the bottom PDMS layer 402 covering the backside of the cell provides electrical insulation as well. Further, the material may be selected to exhibit minimum heat storage. The plural petals 412, after being rolled over the base 401, are bent so that the poles 413 of the petals become adjacent to each other and sides 415 of the petals are in contact with each other. In one application, the sides 415 may be straight edges. In one embodiment, the entire perimeter 417 of one petal becomes in physical contact with the edges of the two adjacent petals 412, so that the 3D shape of the solar cell 100 of FIG. 4D is achieved. To hold the bent petals 412 in shape, in one application, another layer of polydimethylsiloxane (PDMS) material 444, on top of the initial PDMS layer 421, used during the DRIE etching process may be used to coat all the petals and in effect, to “glue” the petals to each other. Thus, according to this approach, after the petals 412 are wrapped around the based 401, they are covered in the PDMS material 444, to fix the petals to each other and/or to the base 401. FIGS. 5A and 5B show the extent of the initial PDMS material 421 which was initially coated over the active material 404 and patterned using the CO₂ laser. This first PDMS material 421 does not adhere to the IBC electrodes 406, and thus, the trenches 407 formed between the various petals are free of the PDMS material. Another PDMS layer 444 would be coated on top of the spherical shaped cell to keep the petals “glued” to each other. This newly added PDMS layer 444 would fill the grooves discussed above. Those skilled in the art would understand that other materials than the PDMS material, may also be used to fix the petals around the base 401, and/or to connect the petals to each other. For example, any polymer that is transparent and flexible (similarly to PDMS) may be used for this purpose.

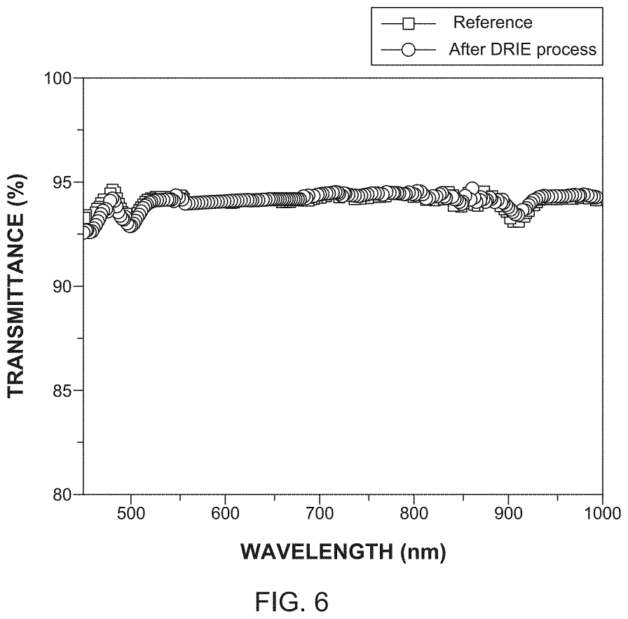

To evaluate the impact of the DRIE processing on the PDMS transparency and therefore to understand the effect of the PDMS material 444 on the efficiency of the 3D solar cell 100, the transmission characteristic of the PDMS layer alone before and after the DRIE processing has been measured, as illustrated in FIG. 6, and it shows no degradation in the optical performance of the PDMS layer over the visible light spectrum.

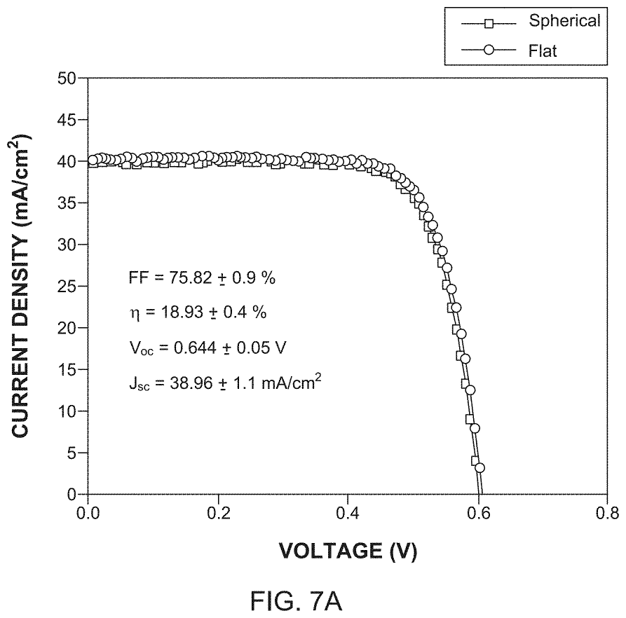

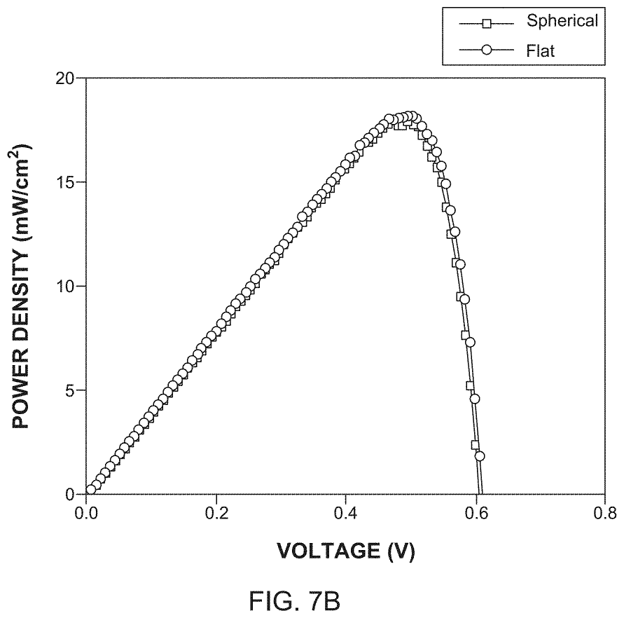

The current density-voltage (J-V) characteristics of the spherical-like solar cell 100 has been compared with a flat solar cell 200, both having the same ground area, using a solar simulator in air (AM 1.5 Global Spectrum with 1000 W m⁻² intensity and spectral mismatch correction at the room temperature). The J-V and power density-voltage characteristic (P-V), shown in FIGS. 7A and 7B, respectively, normalized to the projection area, show that the corrugation technique allows the transformation of the rigid and flat solar cell 200 into a flexible and spherical one 100 with no degradation in the original electrical performance. In this regard, FIG. 7A shows the normalized J-V characteristics of the flat and spherical solar cells with the same ground area (11.34 cm²) with respect to the projection area. FIG. 7B shows the P-V characteristic of both the flat and spherical solar cells with the same ground area. The power density is normalized with respect to the projection area. It is worth to note that the projection area of the spherical solar cell takes into consideration the losses of the active silicon area due to the created trenches (projection area is 10.7 cm² while ground area is 11.34 cm²). The average figures of merit (J, P, efficiency η and fill factor FF) of the spherical solar cell 100 are reported where the error is the standard deviation from 10 characterized devices (see FIG. 7A).

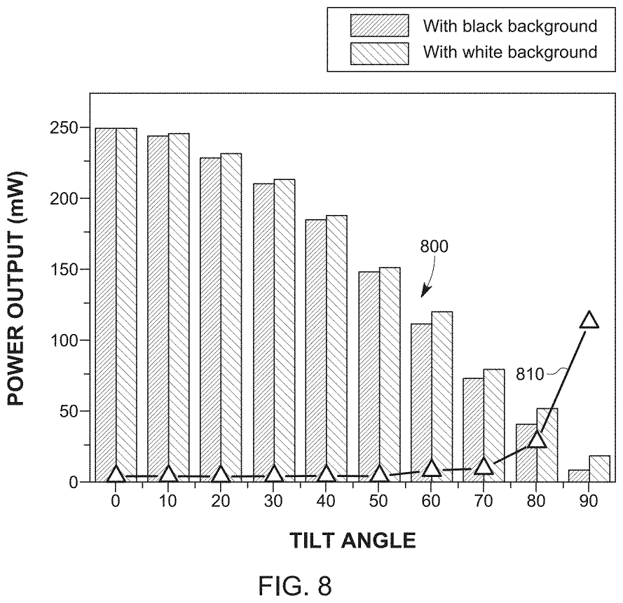

To study the importance of the effective area of a flat solar cell during the day, when the sun orientation varies, the power output produced by the flat solar cell 200 (surface area of 11.34 cm²) at different tilt angles was studied. It was found, as shown in FIG. 8, that as the tilt angle is increased, the angle of incidence of the light is increased and therefore, the power output 800 is reduced. In addition, using a white background as a reflective material, shows an increase in the power output 810 with respect to the case with black background (see FIG. 8). The effect of the white reflective background is most noticeable at 90° (vertical position) due to the capability of the flat solar cell to capture the largest amount of the reflected beam.

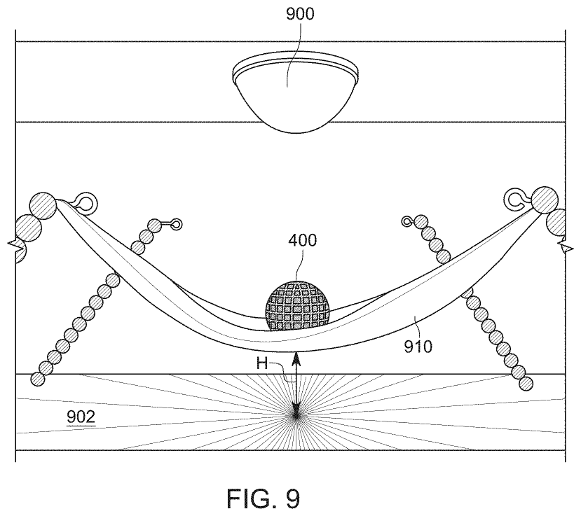

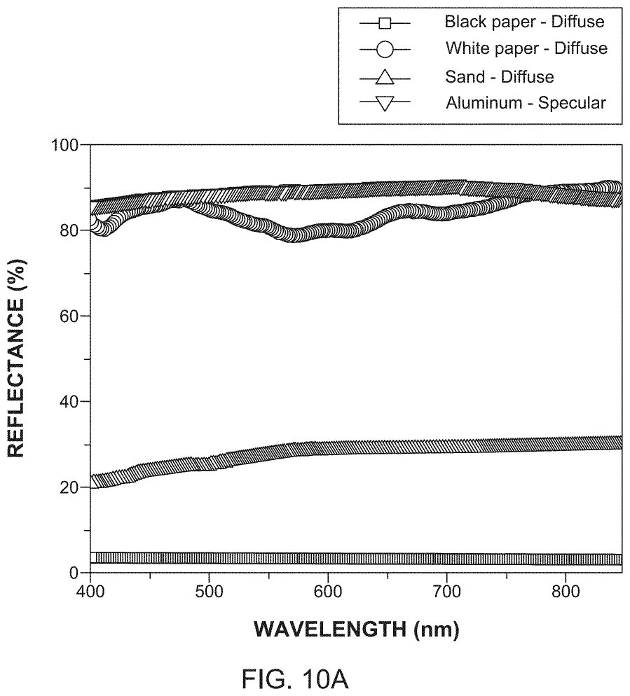

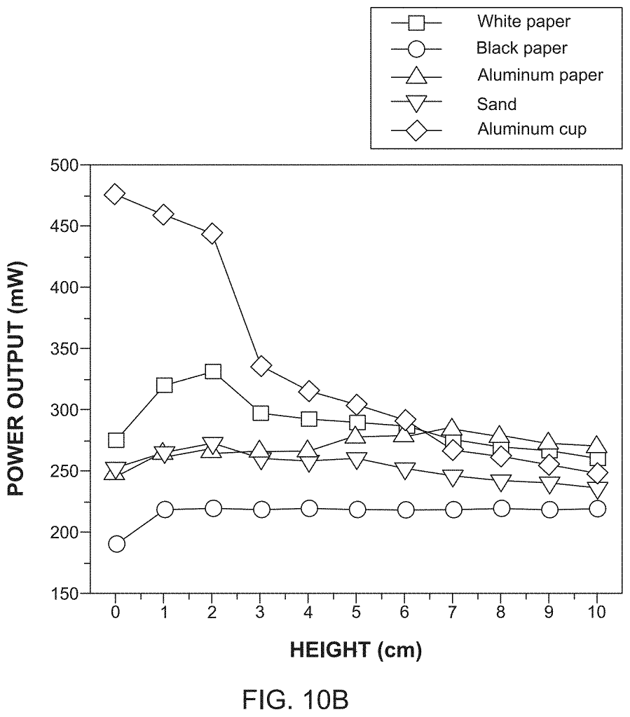

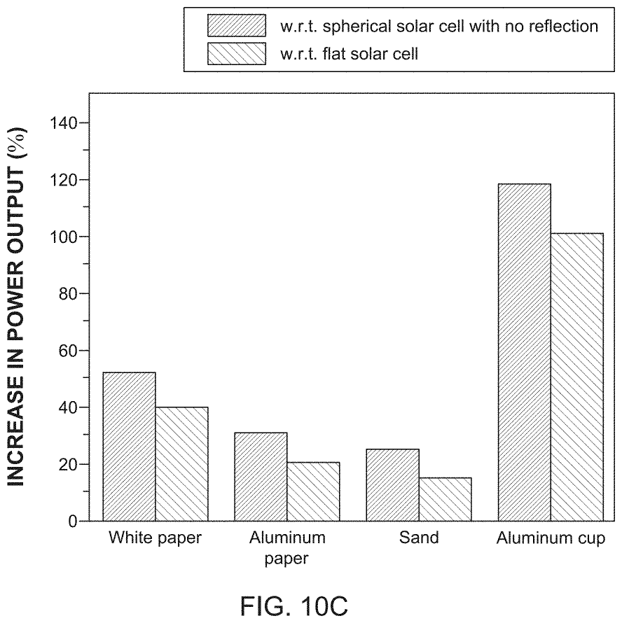

The spherical-like solar cell 100 is capable of exploiting and recycling the background reflected light. To confirm this advantage of the cell 100, the power output of the spherical-like solar cell was measured using a solar simulator 900 under 1 Sun AM 1.5G with different background reflective materials 902 including black paper, white paper, sand, aluminum paper and aluminum cup, as shown in FIG. 9. The 3D solar cell 100 was suspended from a transparent material 910 above the background 902. In addition, the effect of the height H of the spherical solar cell 100, relative to the background 902, on the capability of the solar cell to capture the reflected light was studied. It is worth to note that the white paper and sand show a diffuse reflectance of about 85% and 25%, respectively. The aluminum paper, on the other hand, shows a specular reflectance of about 88%. Finally, the black paper shows a negligible diffuse reflectance of about 3%, as illustrated in FIG. 10A.

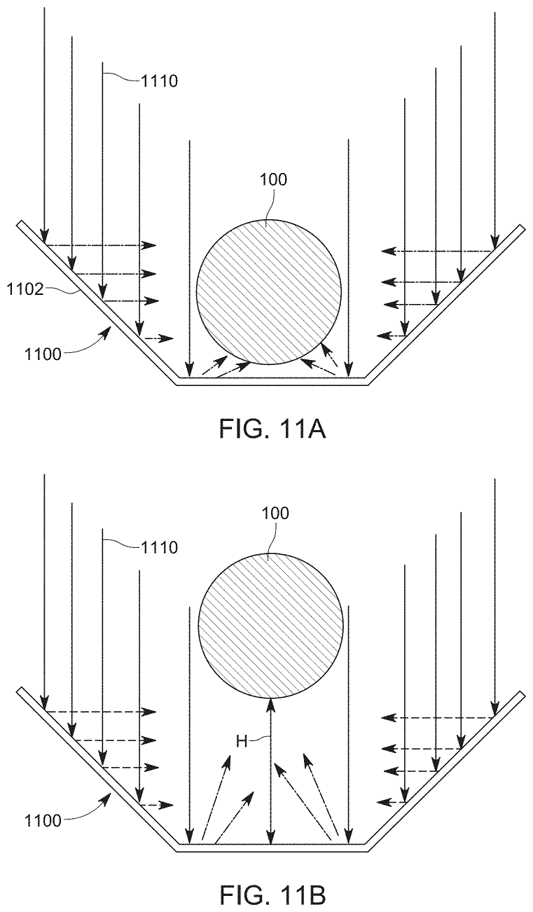

The power output of the cell 100 for the various backgrounds 902 are illustrated in FIG. 10B and the results show that the spherical solar cell is capable of capturing the largest amount of back reflected light when an aluminum cup is used for the background, with a 1 cm height, resulting in a 101% increase in the power output when compared to the flat solar cell 200 with the same ground area, as shown in FIG. 100. In fact, the hexagonal aluminum cup 1100, which is shown in FIGS. 11A and 11B, allows for light reflection back toward the 3D solar cell 100, when the sides 1102 of the cup 1100 make an angle of 45° with a horizontal plane. Following the Snell's law, the incident lights 1110 reflect back with a reflection angle of 45°, allowing the spherical solar cell 100 to capture them, as illustrated in FIGS. 11A and 11B. As the height H of the 3D solar cell 100 relative to the bottom of the aluminum cup 1100 is increased, as shown in FIG. 11B, the reflected light by the bottom parts of the sides of the cup are not entirely captured by the spherical solar cell, and as a result, the output is reduced.

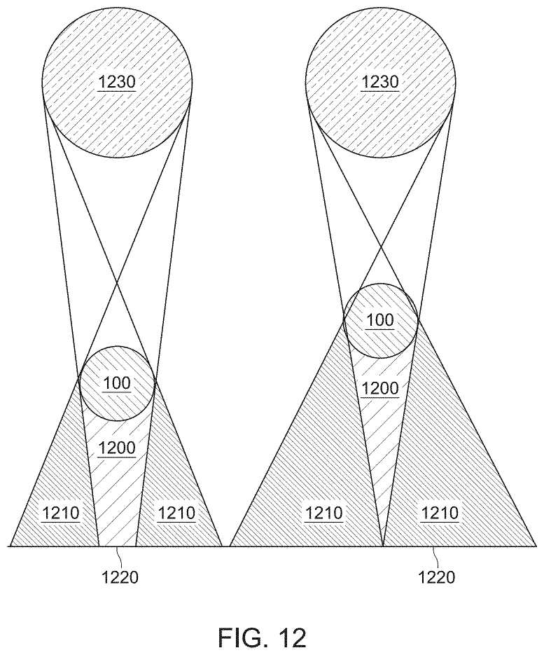

Using white paper as the reflective background material 902, the power output of the 3D solar cell 100 is increased by 39.7% at a height of 2 cm, as shown in FIG. 10C. If the height is increased or decreased from this value, the output is reduced. Similarly, with sand, the largest increase in power output is achieved at a height of 2 cm where the output is enhanced by 14.8% with respect to the flat cell, as shown in FIG. 10C. The lower limit of the spherical solar cell height is determined by the shadowing effect from the solar cell. The shadow is generally composed of umbra 1200, which represents the darkest region of the shadow with no light, and penumbra 1210, which is the lighter region of the shadow with partial light, as illustrated in FIG. 12. As the solar cell 100 is brought closer to the background 1220, the umbra region 1200 is increased, resulting in loss of potential area for light back reflection, as shown in FIG. 12. FIG. 12 also shows a light source 1230, for example the sun.

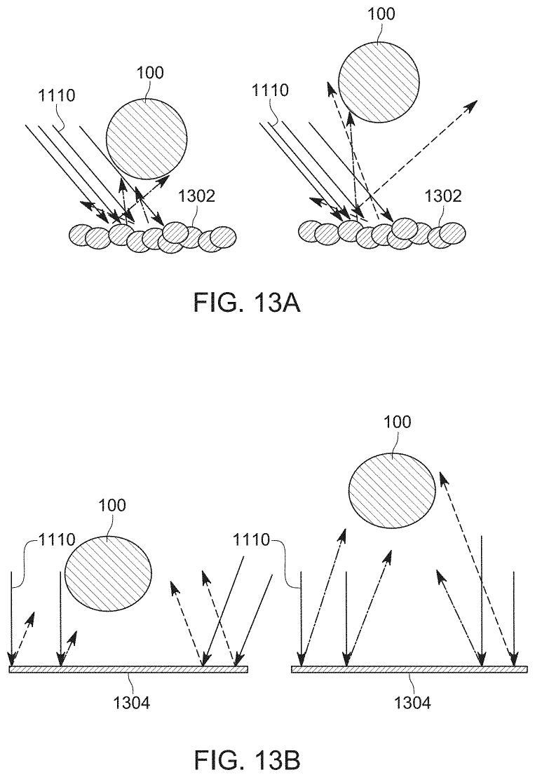

The highest increase in the power output when using aluminum paper with respect to the flat solar cell 200 is obtained at a height of 7 cm. The achieved increase in the power output in this case is only 20.25%, which is considerably smaller than the improvement achieved using white paper (39.7%), even though both materials show similar reflectance values (see FIG. 10C). The reason for this is due to the different type of reflectance obtained in each case. With white paper 1302, diffuse reflection allows the incident light 1110 to reflect in all directions, following Lambert's law, thus increasing the probability of harvesting more light by the spherical solar cell, as illustrated in FIG. 13A. However, the aluminum paper 1304 (see FIG. 13B), having a mirror-like surface, reflects light mainly in one direction, and thus the probability of capturing the reflected light is significantly lower, resulting in a lower power output. In addition, with specular reflection, the higher the solar cell, the higher the probability of harvesting the parallel-reflected rays, which explains the 7 cm needed to maximize the power output. The upper limit for the height of the spherical solar cell is therefore determined by the type of reflectance in addition to the size of the solar cell.

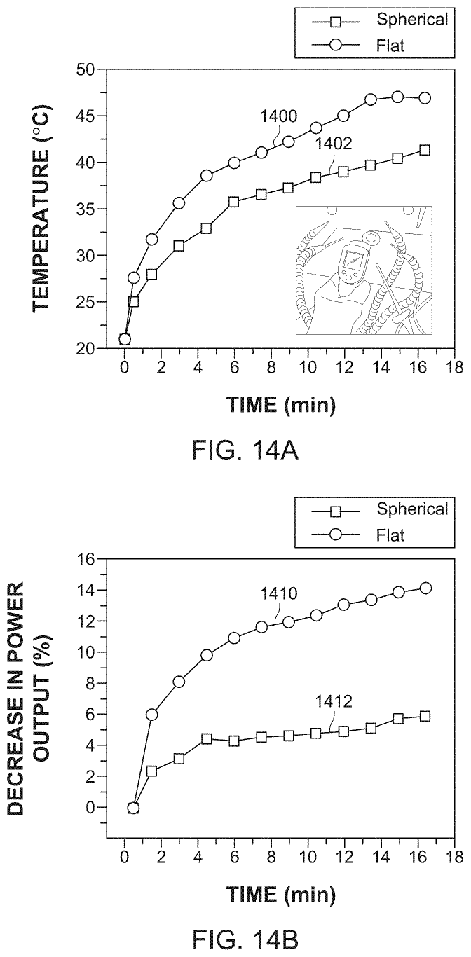

The thermal performance of the novel 3D solar cell 100 is now discussed. Monocrystalline silicon solar cells generally have a temperature coefficient of 0.5%/° C. The spherical structure of the solar cell 100 enables the reduction of heat generation within the cell, and therefore reduce its effect on efficiency degradation. To illustrate this advantage of the 3D solar cell 100, spherical and flat solar cells with the same ground area were continuously exposed to light under 1 Sun AM 1.5G using the solar simulator 900, and the temperature and power output from both cells were measured about every 1.5 min. The temperature measurements 1400 of the flat and rigid solar cell 200 and the temperature measurements 1402 of the 3D solar cell 100 are illustrated in FIG. 14A and the power output decrease measurements 1410 for the flat cell 200 and the power output decrease measurements 1412 for the 3D solar cell 100 are illustrated in FIG. 14B. It is noted that the temperature on the highest point on the 3D cell 100 is recorded for curve 1402, using an infrared sensor, which is expected to show the highest temperature on the spherical structure due to its direct exposure to the perpendicular incoming light rays.

The results in FIG. 14A show that the 3D solar cell 100 provides about 10% lower maximum temperature then the flat solar cell 200 while the power output 1412 shows a 9.6% improvement in FIG. 14B over the power output 1410 of the flat and rigid solar cell. In fact, at a temperature of 47° C. (starting from 21° C.), the flat and rigid solar cell 200 shows a degradation in power output by 14.13%, which is consistent with the monocrystalline silicon temperature coefficient. For the case of the 3D solar cell 100, the temperature reaches 41.2° C. (starting from 21° C.), with a 5.87% degradation in power output. Using the same temperature coefficient, this converts to an average temperature of 32.1° C. for the 3D solar cell 100, which is 31.6% lower than the temperature of the flat cell 200 (47° C.).

The experiments performed with the 3D solar cell 100 show a large range of temperature distribution over the surface of the cell, where the area exposed to the direct light (i.e., light that is perpendicularly to the surface) heats up the most, while other regions of the 3D solar cell 100, which receive light rays with a nonzero angle of incidence, show a reduced temperature. A 12° C. gap between the top (directly exposed to light) and bottom (shadowed) areas of the 3D solar cell 100 was recorded. This means that the top area shows a larger reduction in efficiency than the bottom area. However, in the case of a flat solar cell receiving light rays at the same tilt angle, the temperature will be uniform across its surface area. As a result of this configuration, the integrated power output over the complete surface area of the 3D solar cell 100 was found to be higher than that generated by the flat and rigid cell 200.

Another advantage observed during these experiments is the lower maximum temperature recorded with the 3D solar cell 100 than with the flat and rigid cell 200, 41.2° C. vs. 47° C., respectively, although both regions were receiving light perpendicularly, at 0° incidence angle. To explain the observed result, finite element (FEM) analysis was conducted. Boundary conditions for both geometries were set up and the simulation was conducted to study the heat dissipation in spherical and flat solar cells with the same total surface area when exposed to 1 Sun AM 1.5G for 6 hours with a forced natural convection. The results indicate that the spherical shape of the solar cell 100 allows a reduction in the average temperature by 10% due to heat dissipated by natural convection. For the spherical and flat solar cells with the same ground area, the total surface area of the spherical solar cell is significantly larger than the flat one, thus additional improvement in heat dissipation by natural convection is obtained. This analysis validates the measured results and confirms the advantages of the 3D solar cell (spherical or spherical-like or similar to one of these) in terms of mitigating the heat challenges in solar cells.

Another goal of an improved solar cell, as discussed above, is the dust removal. The accumulation of dust on solar cells acts as a screen and causes a degradation in the cell efficiency and power output over time. To recover the cell efficiency and power output, the traditional solar cells are constantly cleaned. However, actively cleaning the solar cells not only is time and capital intensive, but also require a large amount of water, which is scarce for many of the areas where the large solar farms are located.

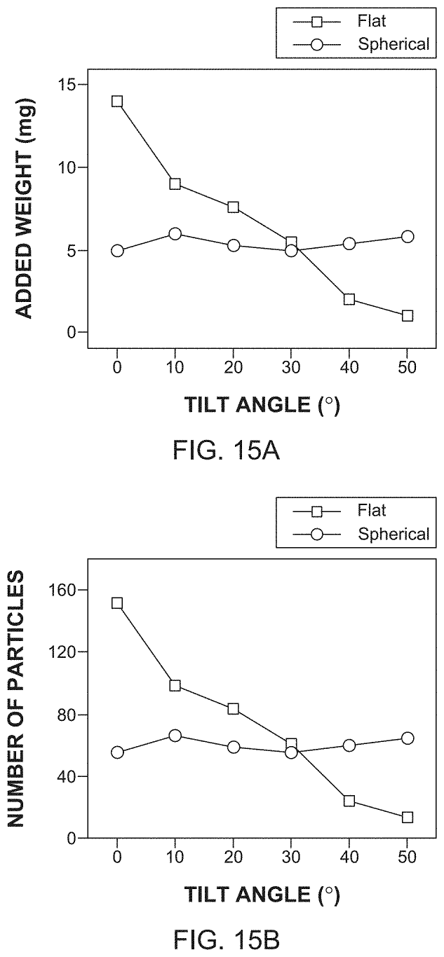

To show the merits of the 3D solar cell 100 over the flat solar cell 200 in terms of dust removal, a customized dust generator is set up to blow 2.04 g of about 140-μm particles over both cells with different tilt angles and same ground area. The weight measurements of the two samples, after the dust generation process, show that the flat and rigid solar cell 200 accumulates more dust at smaller tilt angles, while the spherical solar cell 100 shows a consistent particles accumulation at different tilt angles, as illustrated in FIGS. 15A and 15B. The inventors have also observed that the dust accumulation on the flat structure 200 is most pronounced at tilt angles below 40°. Therefore, to compare the effect of the dust accumulation on both structures, with the same ground area, the area A on the spherical cell which shows tilt angles below 40° was calculated based on the formula:

$$A = {R}^{2} {\int }_{0}^{2 π} d Φ {\int }_{0}^{\frac{π}{4.5}} sin θ d θ = 0.47 π {R}^{2} .$$

This shows that, for the same ground area, the spherical solar cell 100 accumulates dust in a significant manner on an area A of 0.4πR², which is almost half the area available for dust accumulation in the case of the flat and rigid solar cell 200. Thus, the 3D solar cell 100 based on monocrystalline silicon shows better dust management properties when compared with a flat solar cell having the same area.

Therefore, the 3D solar cell 100 discussed above show improvements for most of the objectives of the PV technology. The fabrication of the 3D solar cell 100 is achieved using a corrugation technique that transforms rigid solar cells 400 into flexible ones with no degradation in the original electrical performance. The 3D solar cells 100 were shown to be able to collect and harvest sunlight three-dimensionally, which is an improvement over the existing flat solar cells. More specifically, the 3D solar cell acts as a sun-tracking flat solar cell with the same ground area, and a horizontal and vertical flat cell with twice the ground area in terms of diffuseness and reflected beams, respectively. Using different background reflective materials such as an hexagonal aluminum cup and white paper, the 3D solar cell can achieve an increase in power output by 101% and 39.5%, respectively, with respect to a flat solar cell with the same ground area. In addition, the 3D solar cell shows advantages in terms of heat generation/dissipation where the average temperature is 31.6% lower than the flat cell with the same ground area. The dust accumulation of the flat solar cells is more evident than in the case of the 3D solar cell with the same ground area.

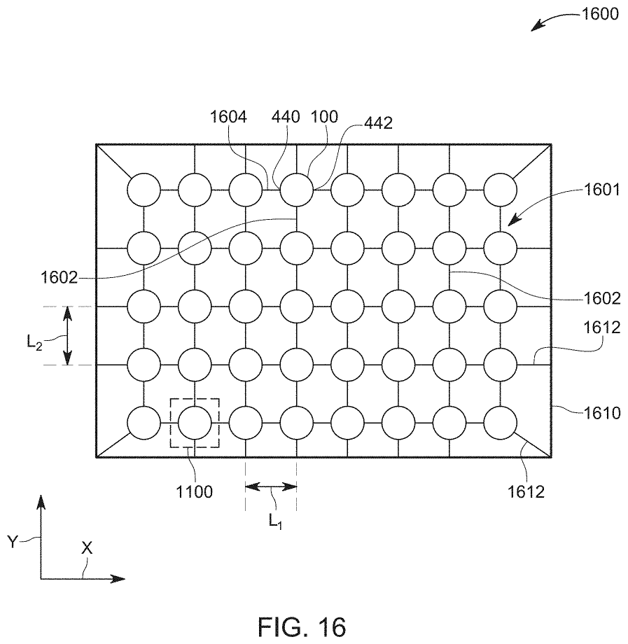

In one embodiment, the 3D solar cell 100 is implemented into a solar cell array 1600 as illustrated in FIG. 16. Such a solar cell array can be located where the traditional solar cell arrays are disposed, for example, on specific supports directly above the ground, on the rooftop of a structure, etc. The solar cell array 1600 includes plural 3D solar cells 100 arranged in a given pattern to form a net. For example, the pattern may fit into a square net or rectangle net or any other shaped net. The pattern may define a network in which the distance L1, between adjacent cells 100 along the X direction, and the distance L2, between adjacent cells 100 along the Y direction, are the same or different. The distances L1 and L2 may be between 1 cm and 10 cm. In one embodiment, the distances L1 and L2 are smaller than 1 cm. As shown in FIG. 16, the solar cells 100 may be arranged uniformly along parallel lines with axis X and parallel lines with axis Y. One skilled in the art would also understand that other arrangements are possible. Each 3D solar cell 100 may be connected with corresponding cell links 1602 to four adjacent 3D solar cells 100. The cell links 1602 may be made of an insulator material, to prevent electrical current to be carried from one cell to another. In one implementation, each cell 100 is linked with conductive cell links 1604 to two adjacent cells for allowing an electrical current to flow from one cell to another while the insulating cell links 1602 are used to only mechanically connected the cells to each other, but not to transmit electrical energy. Thus, by combining the conductive cell links 1604 and the insulating cell links 1602, it is possible to make each cell 100 to be electrically connected to two adjacent cells and also mechanically connected to one or more adjacent cells 100 and/or a frame 1610.

In one application, the frame 1610 may be provided to fully enclose the plural 3D solar cells 100, and all the cells may be attached to the frame 1610 with corresponding links 1612, called frame links herein. The frame links may be made of the same material as the insulating cell links 1602, or a different material. In this way, the frame 1610 may be attached to the traditional supports of the flat solar cells so that a solar farm may be easily retrofitted with the novel 3D solar cells 100.

The fact that the 3D solar cells 100 are attached with frame links 1612 to the frame 1610, and the cells are attached to each other with insulating cell links 1602 and conductive cell links 1604, give the cells 100 the flexibility to slightly move relative to the frame 1610 when deployed, e.g., oscillate, especially if there is air movement around. This movement is beneficial as part of the dust deposited on the surface of the cell 100 is dislodged from surface of the cell, which results in an improved efficiency of the cell. This means that whenever there is air movement around the cells 100, they are able to move relative to the frame 1610, and perform a naturally powered dusting function, which is not possible for the traditional rigid solar cells. In one embodiment, each cell 100 may be provided with a corresponding background material 1100, as discussed above with regard to FIGS. 11A and 11B. The background material 1100 may be any of the materials discussed above. In one application, the background material 1100 is shaped as a cup, as shown in FIG. 11A, and attached to one of the links 1602 and/or 1604 for being located at the desired height H relative to the cell 100.

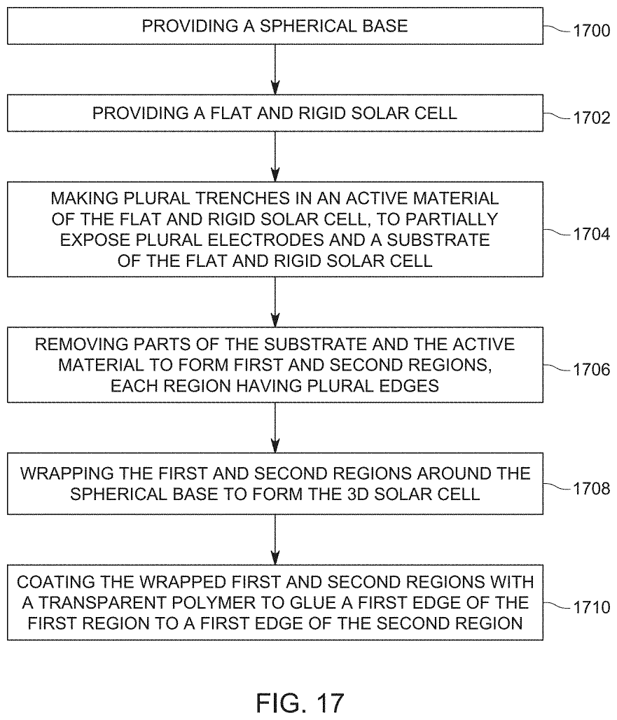

A method for making the 3D solar cell 100 is discussed with regard to FIG. 17. The method includes a step 1700 of providing a spherical base, a step 1702 of providing a flat and rigid solar cell 200, a step 1704 of making plural trenches 407 in the active material 404 of the flat and rigid solar cell 200, to partially expose the plural electrodes 406 and the substrate 402 of the flat and rigid solar cell 200, a step 1706 of removing parts of the substrate 402, the plural electrodes 406, and the active material 404 to form first and second regions 412, each region 412 having plural edges 415, a step 1708 of wrapping the first and second regions 412 around the spherical base 401 to form the 3D solar cell 100, and a step 1710 of coating the wrapped first and second regions 412 with a transparent polymer 420 to glue a first edge 415 of the first region 412 to a first edge 415 of the second region 412.

In one embodiment, the method may further include a step of shaping the first and second regions as petals, and/or attaching, electrically and mechanically, each 3D solar cell to at least another 3D solar cell to form a net of 3D solar cells.

The disclosed embodiments provide a 3D solar cell that harvests light from plural directions, dissipates the generated heat in a more efficient manner than a flat solar cell, and experiences less dust accumulation than the flat solar cell. It should be understood that this description is not intended to limit the invention. On the contrary, the embodiments are intended to cover alternatives, modifications and equivalents, which are included in the spirit and scope of the invention as defined by the appended claims. Further, in the detailed description of the embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

### REFERENCES

[1] T. Minemoto, C. Okamoto, S. Omae, M. Murozono, H. Takakura, and Y. Hamakawa. Japanese journal of applied physics 2005, 44, 4820.
[2] T. Kenichi. Journal of The Japan Institute of Electronics Packaging 2009, 12, 488-491.
[3] R. R. Bahabry, A. T. Kutbee, S. M. Khan, A. C. Sepulveda, I Wicaksono, M. Nour, N. Wehbe, A. S Almislem, M. T. Ghoneim, G. A. Torres Sevilla, A. Syed, S. F. Shaikh, M. M. Hussain. Advanced Energy Materials 2018, 8, 1702221 (2018).

1. A three-dimensional (3D) solar cell comprising:
an active, rigid, and flat material configured to transform solar energy into electrical energy, wherein the active, rigid, and flat material is shaped as first and second petals, each petal having plural sides;
plural electrodes formed on a backside of the active, rigid, and flat material;
a flexible transparent substrate coating the backside of the active, rigid, and flat material and the plural electrodes;
plural trenches formed in the active, rigid, and flat material, to partially expose the plural electrodes and the substrate; and
a transparent polymer configured to attach a side from the first petal to a side from the second petal.

2. The 3D solar cell of claim 1, wherein the first and second petals are wrapped to form a sphere.

3. The 3D solar cell of claim 1, wherein the first and second petals are wrapped to have a spherical-like shape.

4. The 3D solar cell of claim 1, wherein the first and second petals are shaped to have straight edges.

5. The 3D solar cell of claim 1, wherein the first and second petals have one or more grooves formed in the active, rigid, and flat material to expose the plural electrodes and the grooves, which are different from the plural trenches, extend along perpendicular lines.

6. The 3D solar cell of claim 1, wherein the first and second petals are wrapped around a spherical base.

7. The 3D solar cell of claim 1, wherein the transparent polymer fully encapsulates the solar cell.

8. The 3D solar cell of claim 1, wherein the plural electrodes are interdigitated and are made of a bendable metal.

9. A three-dimensional (3D) solar cell comprising:
a spherical base;
plural electrodes wrapped around the spherical base; and
an active material on which the plural electrodes are formed on, and the active material is configured to transform solar energy into electrical energy, wherein the active material is shaped to have plural regions each region having plural sides,
wherein the active material extends over the spherical base and has a spherical shape.

10. The 3D solar cell of claim 9, further comprising:
plural trenches formed in the active material to partially expose the plural electrodes; and
a transparent polymer configured to attach a side of a first region of the plural regions to a side of a second region of the plural regions.

11. The 3D solar cell of claim 9, wherein the plural regions are shaped as petals.

12. A power generation system comprising:
a rigid frame; and
plural solar cells mechanically connected to each other to form a net,
wherein each of the plural solar cells is shaped as a sphere,
wherein the plural solar cells are configured to generate electrical energy from solar energy, and
wherein each solar cell is electrically and mechanically connected to other solar cells of the plural solar cells.

13. The power generation system of claim 12, wherein peripheral solar cells of the net are mechanically attached to the frame.

14. The power generation system of claim 12, wherein a solar cell of the plural solar cells is connected with two conductive links to two other cells of the plural solar cells and with two insulating links to two other cells of the plural solar cells.

15. The power generation system of claim 12, wherein a solar cell comprises:
a spherical base;
plural electrodes wrapped around the spherical base; and
an active material on which the plural electrodes are formed on, and the active material is configured to transform solar energy into electrical energy, wherein the active material is shaped to have plural regions, each region having plural edges,
wherein the active material extends over the spherical base and has a spherical shape.

16. The power generation system of claim 15, further comprising:
plural trenches formed in the active material to partially expose the plural electrodes; and
a transparent polymer configured to glue a side of a first region of the plural regions to a side of a second region of the plural regions.

17. The power generation system of claim 16, wherein the plural regions are shaped as petals.

18-20. (canceled)
